(19) United States
(12) Patent Application Publication
(10) Pub. No.: US 2025/0386703 A1
(43) Pub. Date: Dec. 18, 2025

(54) Display Device

(71) Applicant: LG Display Co., Ltd., Seoul (KR)

(72) Inventors: Yong Woo Yun, Paju-si (KR); Bo Gun Seo, Paju-si (KR); Seung Taek Oh, Paju-si (KR)

(21) Appl. No.: 19/233,253

(22) Filed: Jun. 10, 2025

(30) Foreign Application Priority Data
Jun. 18, 2024 (KR) 10-2024-0078737

(51) Int. Cl. H10K 59/38; H10K 59/40; H10K 59/80

(52) U.S. Cl. CPC H10K 59/38; H10K 59/40; H10K 59/873

(57) ABSTRACT

The present specification discloses a display device. The display device may include a display panel, and an optical element disposed below the display panel and configured to emit light to the outside of the display device and detect light from the outside of the display device, in which the display panel includes a substrate, a encapsulation layer disposed on the substrate, and an optical filter layer disposed between the substrate and the encapsulation layer and configured to filter the emitted light and/or the detected light. The display device has an advantage of increasing the probability that light having a specific wavelength range reaches an object disposed inside or outside the display device.

### CROSS-REFERENCE TO RELATED APPLICATION

This application claims priority to and the benefit of Republic of Korea Patent Application No. 10-2024-0078737, filed Jun. 18, 2024, which is hereby incorporated by reference in its entirety.

### BACKGROUND

### Field

The present specification relates to a display device.

### Discussion of Related Art

Electroluminescence display devices may be classified into inorganic light-emitting display devices and organic light-emitting display devices according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed in each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

Recently, various optical elements are added to mobile terminals with a display panel. The optical elements may be sensors or illumination devices necessary for supporting multimedia functions or performing biological recognition. The optical elements may be assembled below the display panel. Optical elements may be disposed in a notch area (or region) designed in a recessed form at an upper end of a screen of the display panel or in a punch hole area in the screen. Since such optical elements are disposed in the notch area or the punch hole area, the screen of the display panel is limited.

### SUMMARY

An object of the present specification may be to solve the above-described necessity and/or problems in the prior art.

The objectives to be solved by the embodiments of this specification are not limited to the objectives mentioned above, and other objectives not mentioned will be clearly understood by those skilled in the art from the following descriptions.

A display device according to an embodiment of the present specification includes a display panel, and an optical element disposed below the display panel and configured to emit light to the outside of the display device and/or detect light from the outside of the display device, in which the display panel includes a substrate, a encapsulation layer disposed on the substrate, and an optical filter layer disposed between the substrate and the encapsulation layer and configured to filter the emitted light and/or the detected light.

In an embodiment, the display device may further include a light-emitting element disposed between the substrate and the encapsulation layer, and a circuit layer disposed between the substrate and the light-emitting element to drive the light-emitting element, in which the optical filter layer may be disposed between the substrate and the circuit.

In an embodiment, the display device may further include a light-emitting element disposed between the substrate and the encapsulation layer, in which the light-emitting element may include a light-emitting layer, an anode electrode disposed between the substrate and the light-emitting layer, and a cathode electrode disposed between the encapsulation layer and the light-emitting layer, and the optical filter layer may be disposed on the light-emitting element.

In an embodiment, the display device may further include a planarization layer disposed between the substrate and the encapsulation layer, in which the optical filter layer may be disposed on the planarization layer.

In an embodiment, the display device may further include a color filter layer disposed on the encapsulation layer.

In an embodiment, the display device may further include a touch sensor that is disposed on the encapsulation layer and includes a touch sensor electrode, and a band-pass filter disposed to overlap the touch sensor electrode in a thickness direction of the display panel.

In an embodiment, the display panel may include a first area including a first light-emitting area, and a second area including a light-transmitting area and a second light-emitting area, the optical element may include at least one of a first optical element including a light source configured to emit first light, a second optical element including a sensor configured to sense the first light, and a third optical element including a sensor configured to sense second light that has a different wavelength range from that of the first light, and the optical filter layer may include at least one of a first optical filter configured to transmit the first light and a second optical filter configured to transmit the second light.

In an embodiment, the optical element may include the first optical element disposed to overlap the first light-emitting area in a thickness direction of the display panel, and the first light-emitting area may include a first-first light-emitting area disposed to overlap the first optical element in the thickness direction of the display panel.

In an embodiment, the optical filter layer may include the first optical filter disposed to overlap the first-first light-emitting area in the thickness direction of the display panel.

In an embodiment, the optical element may include the first optical element disposed to overlap the second light-emitting area in a thickness direction of the display panel, and the second light-emitting area may include a second-first light-emitting area disposed to overlap the first optical element in the thickness direction of the display panel.

In an embodiment, the optical filter layer may include the first optical filter disposed to overlap the second-first light-emitting area in the thickness direction of the display panel.

In an embodiment, the optical element may include the second optical element disposed to overlap the second light-emitting area in a thickness direction of the display panel, and the second light-emitting area may include a second-second light-emitting area disposed to overlap the second optical element in the thickness direction of the display panel.

In an embodiment, the optical filter layer may include the first optical filter disposed to overlap the second-second light-emitting area in the thickness direction of the display panel.

In an embodiment, the optical element may include the third optical element disposed to overlap the second light-emitting area in a thickness direction of the display panel, and the second light-emitting area may include a second-third light-emitting area disposed to overlap the third optical element in the thickness direction of the display panel.

In an embodiment, the optical filter layer may include the second optical filter disposed to overlap the second-third light-emitting area in the thickness direction of the display panel.

In an embodiment, the optical element may include the first optical element disposed to overlap the light-transmitting area in a thickness direction of the display panel, and the light-transmitting area may include a first light-transmitting area disposed to overlap the first optical element in the thickness direction of the display panel.

In an embodiment, the optical filter layer may include the first optical filter disposed to overlap the first light-transmitting area in the thickness direction of the display panel.

In an embodiment, the optical element may include the second optical element disposed to overlap the light-transmitting area in a thickness direction of the display panel, and the light-transmitting area may include a second light-transmitting area disposed to overlap the second optical element in the thickness direction of the display panel.

In an embodiment, the optical filter layer may include the first optical filter disposed to overlap the second light-transmitting area in the thickness direction of the display panel.

In an embodiment, the optical element may include the third optical element disposed to overlap the light-transmitting area in a thickness direction of the display panel, the light-transmitting area may include a third light-transmitting area disposed to overlap the third optical element in the thickness direction of the display panel.

In an embodiment, the optical filter layer may include the second optical filter disposed to overlap the third light-transmitting area in the thickness direction of the display panel.

In an embodiment, the display panel may include a plurality of pixels, and the pixel density or resolution of the first area may be higher than the pixel density or resolution of the second area.

In an embodiment, the second area may include pixel groups spaced apart from each other by a predetermined distance and the light-transmitting area may be disposed between adjacent pixel groups.

In an embodiment, the first area may include pixel groups spaced apart from each other, and the distance by which the adjacent pixel groups are spaced apart from each other in the second area may be longer than the distance by which adjacent pixel groups are spaced apart from each other in the first area.

In an embodiment, the light-transmitting area may be an area with no pixels and made of transparent insulating materials.

In an embodiment, the first optical filter may block the second light and the second optical filter may block the first light.

In an embodiment, the first light may be infrared ray and the second light may be a visible light beam.

In an embodiment, the first optical element may include an infrared light source or a dot projector, the second optical element may include an infrared camera or an infrared sensor, and the third optical element may include a camera, an image sensor, or a visible light sensor.

In an embodiment, the band-pass filter may include a color filter and a black matrix, the black matrix disposed to overlap the touch sensor electrode in the thickness direction of the display panel.

In an embodiment, the encapsulation layer may include a first encapsulation layer, a second encapsulation layer, and a third encapsulation layer, the first encapsulation layer and the third encapsulation layer being inorganic films, and the second encapsulation layer being an organic film, and the optical filter layer may be disposed between the first encapsulation layer and the second encapsulation layer.

According to the present specification, a reduction in size of the optical element can be accomplished. As a result, the display device can be reduced in thickness.

According to the present specification, when light having a specific wavelength range is desired to reach an element or an object disposed inside or outside the display device, there is an advantage of increasing the probability that the light reaches the element or object disposed inside or outside the display device.

According to the present specification, the improvement of sensing quality of an element can be achieved.

### BRIEF DESCRIPTION OF THE DRAWINGS

The above and other objects, features, and advantages of the present specification will become more apparent to those of ordinary skill in the art by describing exemplary embodiments thereof in detail with reference to the attached drawings, in which:

FIG. 1 is a cross-sectional view schematically illustrating a display device with a display panel and an optical element according to one embodiment of the present specification;

FIG. 2 is a diagram illustrating a part of a display device with an optical element overlapping a second area of a display panel of the display device according to one embodiment of the present specification;

FIG. 3 is a diagram illustrating an example of a display device with optical elements arranged in a second area and a notch area of a display panel of the display device according to one embodiment of the present specification;

FIG. 4 is a block diagram illustrating a display device according to one embodiment of the present specification;

FIG. 5 is a block diagram illustrating an example of a mobile device in which a display device according to one embodiment of the present specification is applied;

FIGS. 6 to 8 are circuit diagrams illustrating various pixel circuits applicable to a display device according to embodiments of the present specification;

FIG. 9 is a plan view illustrating a pixel arrangement in a first area of a display panel of a display device according to one embodiment of the present specification;

FIG. 10 is a plan view illustrating a pixel arrangement in a second area of a display panel of a display device according to one embodiment of the present specification;

FIG. 11 is a chart illustrating optical elements and optical filters that can be disposed in the display device according to the embodiment of the present specification;

FIG. 12 is a plan view illustrating an area of a display panel of the display device where optical elements and optical filters can be disposed according to one embodiment of the present specification;

FIG. 13 is a cross-sectional view illustrating the display device according to one embodiment of the present specification;

FIG. 14 is a chart and a cross-sectional view illustrating optical elements and optical filters disposed by area of the display device according to one embodiment of the present specification;

FIG. 15 is a chart and a cross-sectional view illustrating a first optical element and an optical filter disposed in a light emission area of the display device where the first optical element is disposed according to one embodiment of the present specification;

FIG. 16 is a chart and a cross-sectional view illustrating a second optical element and an optical filter disposed in a light emission area of the display device where the second optical element is disposed according to one embodiment of the present specification;

FIG. 17 is a chart and a cross-sectional view illustrating a third optical element and an optical filter disposed in a light emission area of the display device where the third optical element is disposed according to one embodiment of the present specification; and

FIG. 18 is a chart and a cross-sectional view illustrating a first to third optical elements and optical filters disposed in a light transmission area of the display device where the first to third optical elements are disposed according to one embodiment of the present specification.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

In describing the present disclosure, if it is determined that the detailed description of the related known technology may unnecessarily obscure the subject matter of the present disclosure, the detailed description thereof will be omitted.

When “include”, “have”, “comprise”, or the like mentioned in the present specification, other parts may be added unless “only” is used. In the case where the component is expressed in the singular, the plural includes the plural unless specifically stated otherwise.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms (including technical and scientific terms) used in the embodiments of the present specification may be interpreted in meanings commonly understood by those skilled in the art to which the present disclosure pertains, unless explicitly and specifically defined otherwise, and commonly used terms, such as predefined terms, may be interpreted in consideration of their contextual meanings of the related technology.

In a display device according to the present specification, a pixel circuit and a gate driving circuit may include a plurality of transistors. The transistor may be an oxide thin film transistor (TFT) including an oxide semiconductor or a low temperature polysilicon (LTPS) TFT including LTPS.

The transistor is a three-electrode element including a gate electrode, a source electrode, and a drain electrode. The source electrode is an electrode that supplies carriers to the transistor. In the transistor, the carriers may start from the source electrode. The drain electrode is an electrode through which the carriers flow from the transistor to the outside. In the transistor, the carriers flow from the source electrode to the drain electrode.

In the case of an n-channel transistor, since carriers are electrons, a source voltage is lower than a drain voltage such that the electrons can flow from the source electrode to the drain electrode. In the n-channel transistor, a current flows from the drain electrode to the source electrode. In the case of a p-channel transistor, since carriers are holes, a source voltage is higher than a drain voltage such that the holes can flow from the source electrode to the drain electrode. In the p-channel transistor, since the holes flow from the source electrode to the drain electrode, a current flows from the source electrode to the drain electrode. It should be noted that a source electrode and a drain electrode of a transistor are not fixed. For example, the source electrode and the drain electrode may be changed according to voltages applied thereto. Accordingly, the invention may not be limited due to a source electrode and a drain electrode of a transistor. In the following description, a source electrode and a drain electrode of a transistor may be referred to as first and second electrodes.

Hereinafter, embodiments of the present invention will be described in detail with reference to the accompanying drawings.

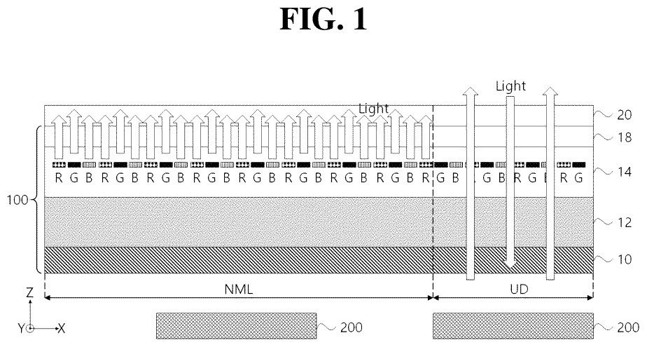

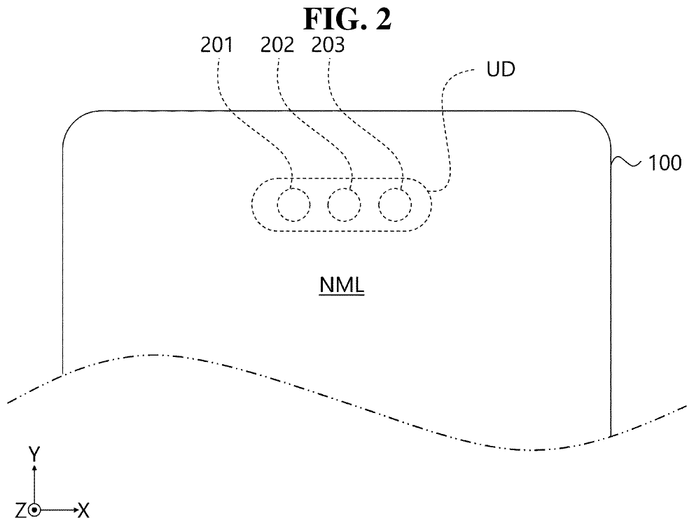

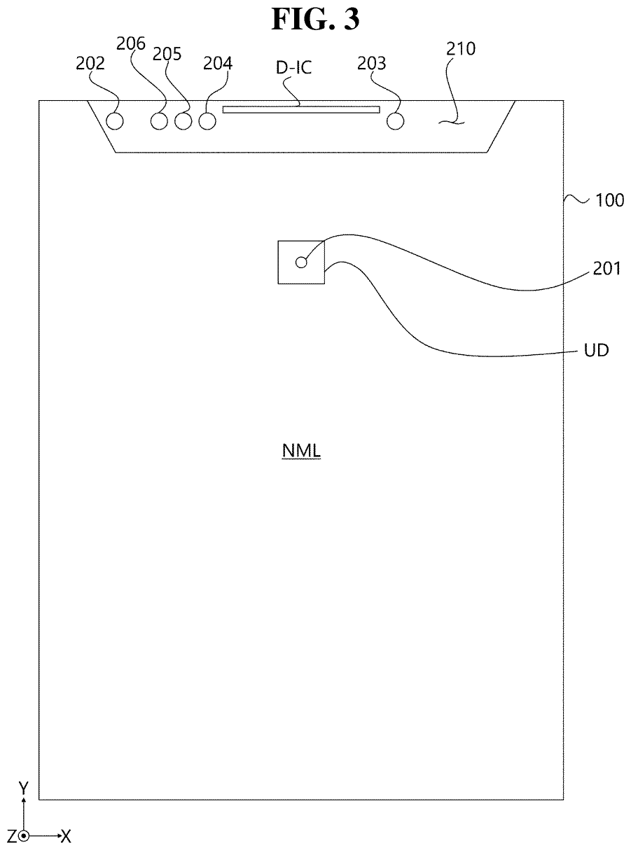

FIG. 1 is a cross-sectional view schematically illustrating a display device with a display panel and an optical element according to one embodiment of the present specification. FIG. 2 is a diagram illustrating a part of a display device with an optical element overlapping a second area of a display panel of the display device according to one embodiment of the present specification. FIG. 3 is a diagram illustrating an example of a display device with optical elements arranged in a second area and a notch area of a display panel of the display device according to one embodiment of the present specification.

Referring to FIGS. 1 to 3, a pixel array constituting a screen of a display panel 100 according to one embodiment of the present specification may include a first area (or region) NML and a second area UD. The first area NML and the second area UD may include pixels into which pixel data of an input image is written. The input image may be displayed in the first area NML and the second area UD.

The first area NML may be a display area in which a plurality of pixels are arranged to reproduce the input image. The first area NML may be larger than the second area UD in size and may be a main display area of the screen where most of the input image is displayed.

The second area UD may be a display area where a plurality of pixels are arranged to reproduce the input image. The pixel density or resolution of the second area UD may be the same or less than that of the first area NML. Pixel density may be interpreted as pixels per inch (PPI). In the present specification, pixel density refers to the number of pixels arranged and driven per the same unit length or area.

The second area UD may include a plurality of light-transmitting parts without a light blocking medium, but is not limited thereto. The light-transmitting parts may be positioned between sub-pixels. Light may pass through the light-transmitting parts with little loss. If the light-transmitting parts of the second area UD are enlarged to increase the amount of light received by an optical element disposed below the display panel through the second area UD, the pixel density of the second area UD may decrease due to the area of the light-transmitting parts, so the pixel density or resolution of the second area UD may become lower than that of the first area NML.

Each of the pixels in the first area NML and the second area UD may include sub-pixels of different colors to implement the color of an image. The sub-pixels may include red, green, and blue sub-pixels. Hereinafter, the red sub-pixel may be abbreviated as “R sub-pixel”, the green sub-pixel may be abbreviated as “G sub-pixel”, and the blue sub-pixel may be abbreviated as “B sub-pixel”. Each of the pixels may further include a white sub-pixel (hereinafter, abbreviated as “W sub-pixel”). Each of the sub-pixels may include a pixel circuit that drives a light emitting element.

At least one optical element 200 may be disposed below a rear surface of the display panel 100 to overlap the first area NML of the display panel 100. Internal light generated in the optical element 200 may travel to an object outside the display device through the first area NML.

At least one optical element 200 may be disposed below the rear surface of the display panel 100 to overlap the second area UD of the display panel 100. External light may travel to the optical element 200 disposed below the display panel 100 through the second area UD.

The optical element 200 may include one or more of an image sensor, a proximity sensor, a white light illuminator, and an optical element for face recognition.

The optical element for face recognition may include a first optical element, a second optical element, an infrared illuminator, and the like disposed below the second area UD of the display panel 100.

Referring to FIG. 3, a second optical element 202, a third optical element 203, an ambient light sensor 204, a proximity sensor 205, a flood illuminator 206 may be disposed in a notch area 210 of a mobile terminal, and a first optical element 201 may be disposed in a second area UD in one embodiment. The notch area 210 may be a non-display area with no pixels at an upper end of a mobile terminal screen. However, the present specification is not limited thereto, and the first optical element 201 may be disposed in the first area NML excluding the notch area 210 and the second area UD.

In the display device according to the present specification, since the optical elements 200 are disposed below the rear surface of the display panel 100 to overlap the second area UD, a display area of the screen may not be limited due to the optical elements 200. Accordingly, with the display device according to the present specification, the display area of the screen can be enlarged to implement full-screen display, and the degree of freedom for screen design can be increased.

The display panel 100 may have a width in the X-axis direction, a length in the Y-axis direction, and a thickness in the Z-axis direction. The X-axis direction and the Y-axis direction may intersect each other in the plane of the display panel 100. For example, the X-axis direction and the Y-axis direction may be perpendicular to each other.

The display panel 100 may include a circuit layer 12 positioned on a substrate 10, and a light emitting element layer 14 positioned on the circuit layer 12. A polarizing plate 18 may be positioned on the light emitting element layer 14, and a cover glass 20 may be positioned on the polarizing plate 18.

The circuit layer 12 may include a pixel circuit connected to wires such as data lines, gate lines intersecting the data lines, and power lines, and a gate driver connected to the gate lines. The circuit layer 12 may include circuit elements such as transistors implemented as thin film transistors (TFTs) and a capacitor. The circuit elements and wiring of the circuit layer 12 may be implemented with a plurality of insulating layers, two or more metal layers separated by the plurality of insulating layers interposed therebetween, and an active layer including a semiconductor material.

The light emitting element layer 14 may include a light emitting element driven by the pixel circuit. The light emitting element may be implemented as an OLED. The OLED may include an organic compound layer formed between an anode electrode and a cathode electrode. The organic compound layer may include a hole injection layer (HIL), a hole transport layer (HTL), an emission layer (EML), an electron transport layer (ETL), and an electron injection layer (EIL), but is not limited thereto. When a voltage is applied to the anode electrode and cathode electrode of the OLED, holes that have passed through the hole transport layer (HTL) and electrons that have passed through the electron transport layer (ETL) move to the emission layer (EML) to form excitons, thereby allowing visible light to be emitted from the emission layer (EML). The OLED used as the light emitting element may have a tandem structure in which a plurality of emission layers are stacked. The OLED with a tandem structure may improve the luminance and lifespan of the pixels. The light emitting element layer 14 may further include a color filter array positioned above the light emitting element to selectively transmit red, green, and blue wavelengths.

The light emitting element layer 14 may be covered with a protective layer, and the protective layer may be covered with an encapsulation layer. The protective layer and the encapsulation layer may have a multi-insulating film structure in which organic and inorganic films are alternately stacked. The inorganic film may block the permeation of moisture or oxygen. The organic film may planarize the surface of the inorganic film. When the organic and inorganic films are stacked in multiple layers, the movement path of moisture or oxygen may become longer than that in a single layer, effectively blocking the permeation of moisture and oxygen affecting the light emitting element layer 14.

A touch sensor layer (not shown) may be formed on the encapsulation layer, and the polarizing plate 18 or a color filter layer may be positioned on the touch sensor layer. The touch sensor layer may include capacitive touch sensors that sense touch input based on changes in capacitance before and after a touch input. The touch sensor layer may include metal wiring patterns and insulating films that form the capacitance of the touch sensors. The insulating films may insulate an intersecting portion in the metal wiring patterns and planarize the surface of the touch sensor layer.

The polarizing plate 18 may convert the polarization of external light reflected by the metal of the touch sensor layer and the circuit layer to improve visibility and contrast. The polarizing plate 18 may be implemented as a linear polarizing plate bonded with a phase retardation film or a circular polarizing plate. The cover glass 20 may be bonded onto the polarizing plate 18. The color filter layer positioned on the touch sensor layer may include red, green, and blue color filters. The color filter layer may further include a black matrix pattern. The color filter layer may absorb a portion of the wavelength of light reflected from the circuit layer and the touch sensor layer, thereby serving as a substitute for the polarizing plate 18 and increasing the color purity of the image reproduced in the pixel array. In this case, the polarizing plate 18 may not be provided.

The above-described configurations are explained in more detail through the cross-sectional views described below.

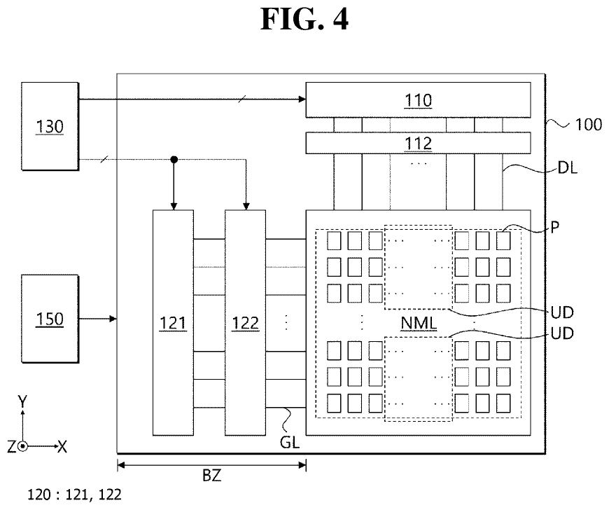

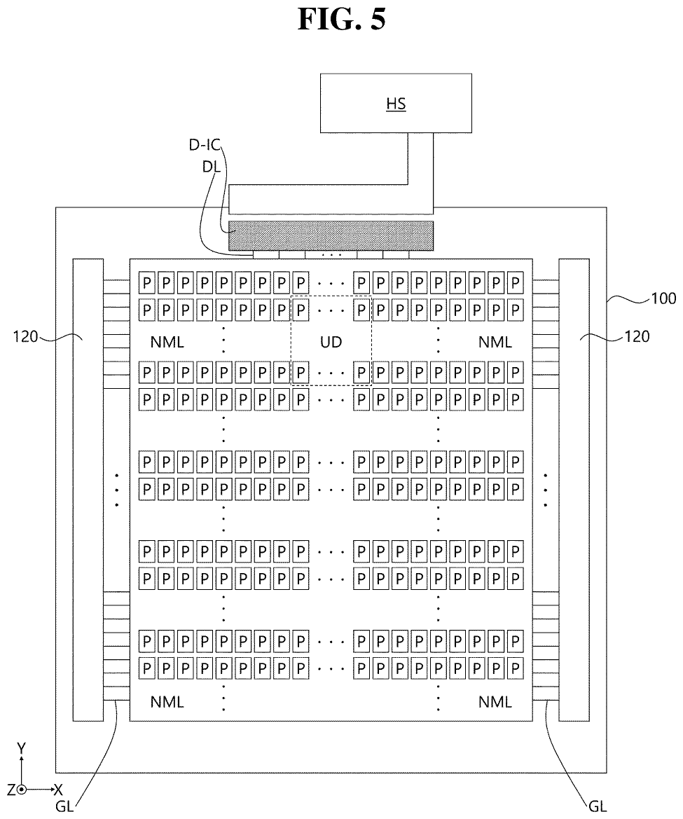

FIG. 4 is a block diagram illustrating a display device according to one embodiment of the present specification. FIG. 5 is a block diagram illustrating an example of a mobile device in which a display device according to one embodiment of the present specification is applied.

Referring to FIGS. 4 and 5, the display device according to one embodiment of the present specification may include the display panel 100, a display panel driver for writing the pixel data of the input image to pixels P of the display panel 100, a timing controller 130 for controlling the display panel driver, and a power supply 150 for generating power necessary for driving the display panel 100.

The display panel 100 may include a pixel array for displaying the input image on the screen. The pixel array may be divided into the first region NML and the second region UD as described above.

The touch sensors may be arranged on the screen of the display panel 100 constituted by the pixel array.

The display panel 100 may be implemented as a flexible display panel in which the pixels P are arranged on a flexible substrate such as a plastic substrate or a metal substrate.

The display panel driver may reproduce the input image on the screen of the display panel 100 by writing the pixel data of the input image to the sub-pixels. The display panel driver may include a data driver 110 (also shown as “D-IC” in FIGS. 3, 5) and a gate driver 120. The display panel driver may further include a demultiplexer 112 positioned between the data driver 110 and data lines DL.

The display panel driver may operate in a low-speed driving mode under the control of the timing controller 130.

The data driver 110 may convert the pixel data of the input image, which is digital data, using a digital-to-analog converter (hereinafter referred to as “DAC”) to generate a data voltage Vdata. The data voltage Vdata outputted from each of the channels of the data driver 110 may be supplied to the data lines DL of the display panel 100 or may be supplied to the data lines DL through the demultiplexer 112.

The demultiplexer 112 may distribute the data voltage Vdata outputted through the channels of the data driver 110 to the plurality of data lines DL in a time-division manner. The number of channels of the data driver 110 may be reduced due to the demultiplexer 112.

The gate driver 120 may shift a gate signal using a shift register to sequentially supply the gate signals to gate lines GL.

The gate driver 120 may be arranged on each of the left and right bezels of the display panel 100 and supply the gate signals to the gate lines GL in a double feeding manner.

The gate driver 120 may include a first gate driver 121 and a second gate driver 122. The first gate driver 121 may output a scan pulse and a sensing pulse and may shift the scan pulse and the sensing pulse according to a shift clock. The second gate driver 122 may output an EM pulse and may shift the EM pulse according to the shift clock.

The timing controller 130 may receive the pixel data of the input image and a timing signal synchronized with the pixel data from a host system HS. The timing signal may include a vertical synchronization signal Vsync, a horizontal synchronization signal Hsync, a clock CLK, and a data enable signal DE.

The timing controller 130 may transmit the pixel data of the input image to the data driver 110 and may synchronize the data driver 110, the demultiplexer 112, and the gate driver 120.

The timing controller 130 may multiply an input frame frequency by i (i being a positive integer greater than zero) to control the operation timing of the display panel driver (110, 112, and 120) at a frame frequency of the input frame frequency×i Hz.

Based on the timing signal (Vsync, Hsync, and DE) received from the host system HS, the timing controller 130 may generate a data timing control signal for controlling the operation timing of the data driver 110, and a gate timing control signal for controlling operation timing of the gate driver 120.

The voltage level of the gate timing control signal outputted from the timing controller 130 may be converted to a gate high voltage VGH/VEH and a gate low voltage VGL/VEL through a level shifter, which is omitted from the drawings, and supplied to the gate driver 120. The level shifter may receive a clock of the gate timing control signal from the timing controller 130 and output a timing signal, such as a start pulse and a shift clock, necessary for driving the gate driver 120.

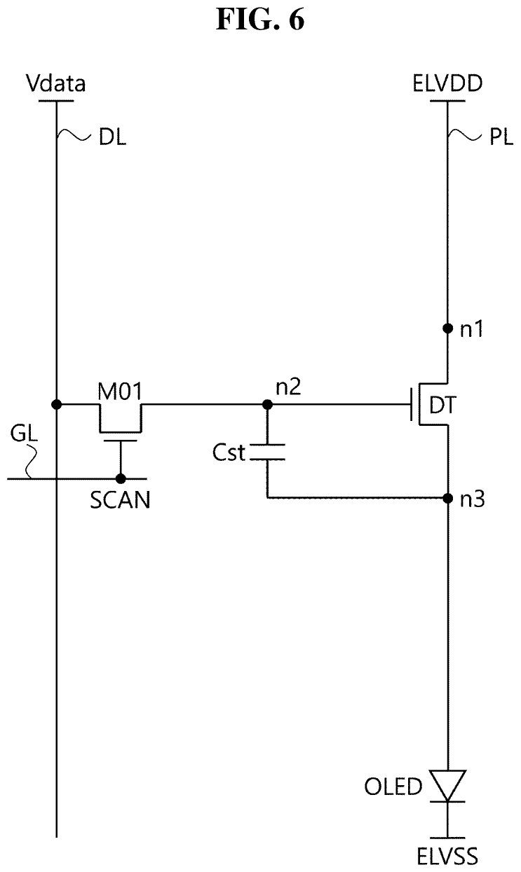

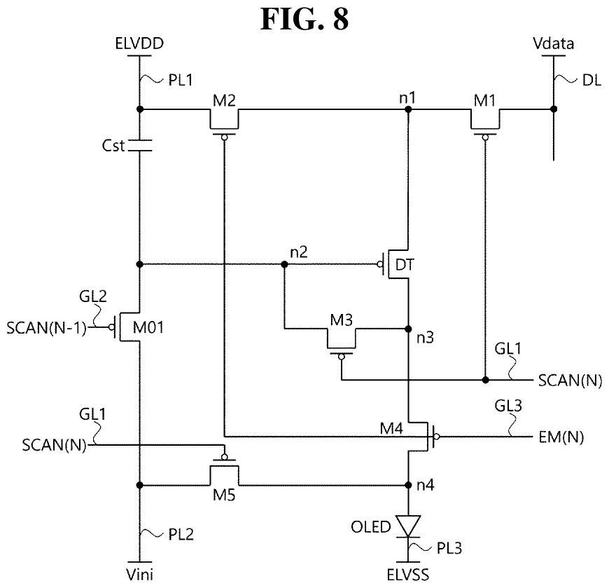

The power supply 150 may adjust a direct current (DC) input voltage from the host system HS to generate power necessary for driving the display panel 100 and the display panel driver. The power supply 150 may output DC voltages such as a gamma reference voltage, a gate-off voltage VGH/VEH, a gate-on voltage VGL/VEL, a pixel driving voltage ELVDD (see FIG. 6), a low potential power voltage ELVSS (see FIG. 6), an initialization voltage Vini (see FIG. 8), and a reference voltage VREF.

The host system HS may be a main circuit board of a television (TV) system, a set-top box, a navigation system, a personal computer (PC), a vehicle system, a home theater system, a mobile device, or a wearable device. The host system HS may include an authentication module.

FIGS. 6 to 8 are circuit diagrams illustrating various pixel circuits applicable to a display device according to embodiments of the present specification.

Referring to FIG. 6, the pixel circuit may include a light emitting element OLED, a driving element DT that supplies a current to the light emitting element OLED, a switch element M01 that connects the data line DL to a second node n2 in response to a scan pulse SCAN, and a capacitor Cst connected between the second node n2 and a third node n3. The driving element DT and the switch element M01 may be implemented as n-channel transistors.

The driving element DT may include a gate electrode connected to the second node n2, a first electrode connected to a first node n1, and a second electrode connected to the third node n3. A VDD line PL, to which the pixel driving voltage ELVDD is applied, may be connected to the first node n1. The light emitting element OLED may include an anode electrode connected to the third node n3, and a cathode electrode connected to a VSS line to which the low potential power voltage ELVSS is applied.

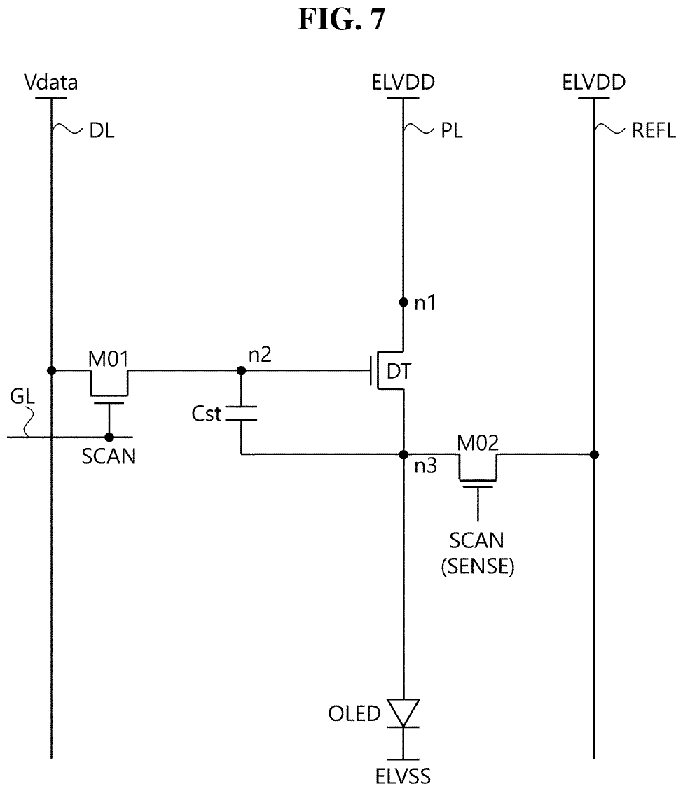

Referring to FIG. 7, the pixel circuit may further include a second switch element M02 connected between a reference voltage line REFL and the second electrode of the driving element DT. In this pixel circuit, the driving element DT and the switch elements M01 and M02 may be implemented as n-channel transistors.

Referring to FIG. 8, the pixel circuit may include a light emitting element OLED, a driving element DT that supplies a current to the light emitting element OLED, and a switching circuit that switches voltages applied to the light emitting element OLED and the driving element DT.

The switching circuit may include an internal compensation circuit that samples a threshold voltage Vth of the driving element DT using a plurality of switch elements M01, M1 to M5 to store it in a capacitor Cst, and compensates the gate voltage of the driving element DT by the threshold voltage Vth of the driving element DT. Each of the driving element DT and the plurality of switch elements M01, M1 to M5 may be implemented as a p-channel TFT.

The anode electrode of the light emitting element OLED may be connected to a fourth node n4 between a fourth switch element M4 and a fifth switch element M5. The fourth node n4 may be connected to the anode electrode of the light emitting element OLED, the second electrode of the fourth switch element M4, and the second electrode of the fifth switch element M5. The cathode electrode of the light emitting element OLED may be connected to a VSS line PL3 to which the low potential power voltage ELVSS is applied.

The capacitor Cst may be connected between a VDD line PL1 and a second node n2.

The driving element DT may drive the light emitting element OLED by adjusting the current flowing through the light emitting element OLED according to a gate-to-source voltage Vgs. The driving element DT may include a gate electrode connected to the second node n2, a first electrode connected to a first node n1, and a second electrode connected to a third node n3.

It should be noted that the pixel circuit is not limited to those shown in FIGS. 6 to 8. For example, the data voltage Vdata may be applied to the gate electrode of the driving element DT, or may be applied to the first electrode or second electrode of the driving element DT.

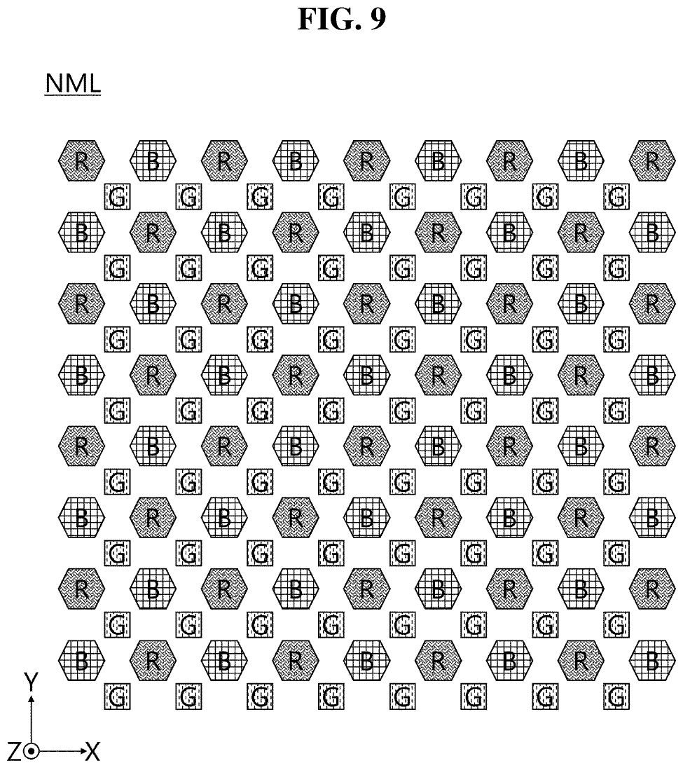

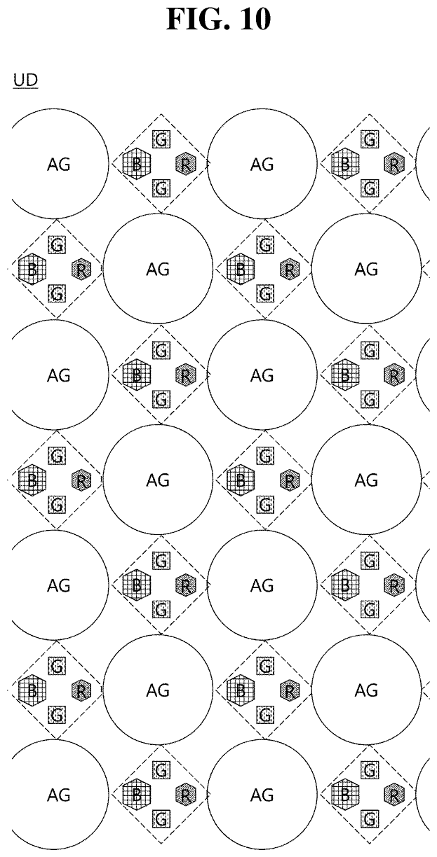

FIG. 9 is a plan view illustrating a pixel arrangement in the first area of the display panel of the display device according to one embodiment of the present specification. FIG. 10 is a plan view illustrating a pixel arrangement in the second area of the display panel of the display device according to one embodiment of the present specification.

Referring to FIG. 9, the first area NML may include the plurality of pixels. Each of the pixels may be implemented as a real-type pixel in which R, G, and B sub-pixels of the three primary colors constitute a single pixel. Each of the pixels may further include a W sub-pixel, which is omitted from the drawing.

The pixel density or resolution of the first area NML may be greater than the pixel density or resolution of the second area. As will be described later, the reference symbol for the second area is UD.

Each of the pixels may be configured as a pixel composed of two sub-pixels using a sub-pixel rendering algorithm. For example, a first pixel may be composed of an R sub-pixel and a first G sub-pixel, and a second pixel may be composed of a B sub-pixel and a second G sub-pixel. In each of the first and second pixels, the deficiency in color representation may be compensated by averaging the corresponding color data among adjacent pixels.

The sub-pixels may have different luminous efficiencies of the light emitting elements depending on the color. In consideration of this, the sizes of the sub-pixels may differ depending on their colors. For example, among the R, G, and B sub-pixels, the size of the B sub-pixel may be the largest and the size of the G sub-pixel may be the smallest.

Referring to FIG. 10, the second area UD may include pixel groups spaced apart from each other by a predetermined distance, and light-transmitting parts (or areas) AG disposed between adjacent pixel groups. Due to the light-transmitting parts AG, the distance by which the adjacent pixel groups are spaced apart from each other in the second area UD may be longer than the distance by which the adjacent pixel groups are spaced apart from each other in the first area NML. The pixel groups disposed in an area indicated by a dotted line may include a plurality of subpixels.

The light-transmitting parts AG may be an area with no pixels. Thus, the light-transmitting parts AG lack any pixels. The light-transmitting parts AG may be made of transparent insulating materials without including metal lines or pixels. While a pixel density in the second area UD is low due to the light-transmitting parts AG, since average light transmittance in the second area UD is higher than that in the first area NML, the amount of light received by the optical elements disposed below the display panel may increase. The light-transmitting parts AG have a circular shape, but are not limited thereto. For example, the light-transmitting parts AG may be designed in various shapes such as a circular shape, an elliptical shape, a polygonal shape, and an angular shape.

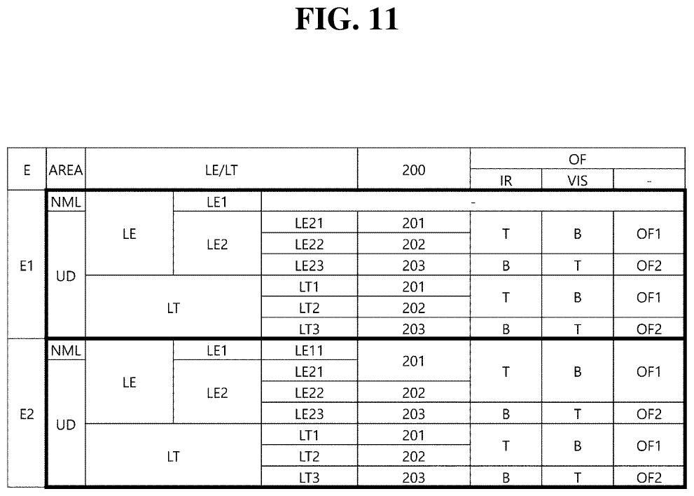

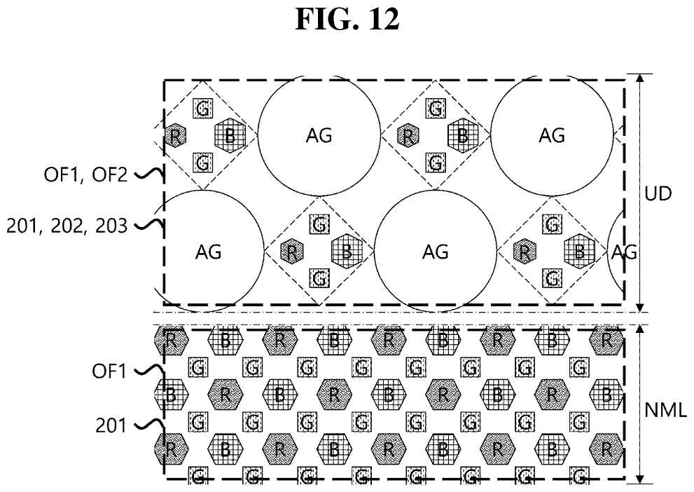

FIG. 11 is a chart illustrating optical elements and optical filters that may be disposed in the display device according to one embodiment of the present specification. FIG. 12 is a plan view illustrating an area of the display panel where optical elements and optical filters may be disposed according to one embodiment of the present specification. In the chart of FIG. 11, ‘E’ may indicate embodiments, ‘T’ may indicate transmitting and ‘B’ may indicate blocking.

Referring to FIGS. 11 and 12, the display device may include a display panel including the first area NML and the second area UD. The first area NML may include a first light-emitting area LE1. The second area UD may include a second light-emitting area LE2 and a light-transmitting area LT.

The light-emitting area LE may include a first light-emitting area LE1 and a second light-emitting area LE2. The first light-emitting area LE1 may include a first-first light-emitting area LE11. The second light-emitting area LE2 may include a second-first light-emitting area LE21, a second-second light-emitting area LE22, and a second-third light-emitting area LE23. The light-transmitting area LT may include a first light-transmitting area LT1, a second light-transmitting area LT2, and a third light-transmitting area LT3.

A display device according to a first embodiment E1 may include a second area UD where an optical element 200 is disposed. The display device according to the first embodiment E1 may be applied to, for example, a mobile terminal. However, the present specification is not limited thereto, and the display device may also be applied to a display for a vehicle. A display device according to a second embodiment E2 may include a first area NML where an optical element 200 is disposed and a second area UD where an optical element 200 is disposed. The display device according to the second embodiment E2 may be applied to, for example, a display for a vehicle. However, the present specification is not limited thereto, and the display device may also be applied to a mobile terminal.

The illustrated chart shows light-emitting areas LE, optical elements 200, or optical filters OF that “may be” disposed in the first area NML and/or the second area UD, and all of the specified light-emitting area LE, optical elements 200, and optical filters OF are not needed to be disposed.

For example, the display device according to the embodiment may include a second light-emitting area LE2. According to the chart, the second light-emitting area LE2 may include a second-first light-emitting area LE21, a second-second light-emitting area LE22, and a second-third light-emitting area LE23. However, the display device according to the above-described embodiment including the second light-emitting area LE2 does not need to include all of the above-described light-emitting areas LE21, LE22, and LE23. As described below, corresponding optical element 200 and optical filter OF may be disposed in each of the light-emitting areas LE21, LE22, and LE23. Accordingly, the display device according to the above-described embodiment including the second light-emitting area LE2 does not need to include all of the first optical element 201, the second optical element 202, and the third optical element 203. Furthermore, the display device does not need to include both of a first optical filter OF1 and a second optical filter OF2. The display device according to the above-described embodiment may include at least one of the above-described light-emitting areas LE21, LE22, and LE23 that may be included in the second light-emitting area LE2.

As another example, the display device according to the embodiment may include a light-transmitting area LT. According to the chart, the light-transmitting area LT may include a first light-transmitting area LT1, a second light-transmitting area LT2, and a third light-transmitting area LT3. However, the display device according to the above-described embodiment including the light-transmitting area LT does not need to include all of the above-described light-transmitting areas LT1, LT2, and LT3. As described below, corresponding optical element 200 and optical filter OF may be disposed in each of the above-described light-transmitting areas LT1, LT2, and LT3. Accordingly, the display device according to the above-described embodiment including the light-transmitting area LT does not need to include all of the first optical element 201, the second optical element 202, and the third optical element 203. Furthermore, the display device does not need to include both of the first optical filter OF1 and the second optical filter OF2. The display device according to the above-described embodiment may include at least one of the above-described light-transmitting areas LT1, LT2, and LT3 that may be included in the light-transmitting area LT.

Accordingly, display devices according to various embodiments including the second light-emitting area LE2 and/or the light-transmitting area LT can be derived according to the chart.

If a light-emitting area LE is specified, an optical element 200 may be specified. The optical element 200 may be any one of the first optical element 201, the second optical element 202, and the third optical element 203. For example, the first optical element 201 may be disposed in the first-first light-emitting area LE11. For example, the first optical element 201 may be disposed in the second-first light-emitting area LE21. The second optical element 202 may be disposed in the second-second light-emitting area LE22. The third optical element 203 may be disposed in the second-third light-emitting area LE23. The first optical element 201 may be disposed in the first light-transmitting area LT1. The second optical element 202 may be disposed in the second light-transmitting area LT2. The third optical element 203 may be disposed in the third light-transmitting area LT3.

The optical filter OF may be any one of a first optical filter OF1 that transmits first light IR and a second optical filter OF2 that transmits second light VIS. The optical filter OF may be any one of a first optical filter OF1 that transmits the first light IR and blocks the second light VIS and a second optical filter OF2 that blocks the first light IR and transmits the second light VIS. The degree of transmitting and blocking light is not limited. Blocking may include reflecting.

For example, the first optical filter OF1 may have the degree of transmitting the first light IR greater than the degree of transmitting the second light VIS. For example, the second optical filter OF2 may have the degree of transmitting the second light VIS greater than the degree of transmitting the first light IR. For example, the first optical filter OF1 may have the degree of blocking the first light IR smaller than the degree of blocking the second light VIS. For example, the second optical filter OF2 may have the degree of blocking the second light VIS smaller than the degree of blocking the first light IR.

In an embodiment, the first optical element 201 may include an infrared light source or a dot projector, but the present specification is not limited thereto. In an embodiment, the second optical element 202 may include an infrared camera or an infrared sensor, but the present specification is not limited thereto. In an embodiment, the third optical element 203 may include a camera, an image sensor, or a visible light sensor, but the present specification is not limited thereto.

In an embodiment, the first light IR may be infrared rays. In an embodiment, the second light VIS may be a visible light beam. However, the present specification is not limited thereto. A wavelength range of the first light IR may be 800 nm to 1100 nm. Specifically, the wavelength range of the first light IR may be 850 nm to 940 nm. A wavelength range of the second light VIS may be 400 nm to 800 nm. However, the wavelength range is not specified to numerical values and may be changed within a range obvious to those of ordinary skill in the art.

The first optical filter OF1 may be disposed to correspond to the first optical element 201. The first optical filter OF1 may be disposed to correspond to the second optical element 202. The second optical filter OF2 may be disposed to correspond to the third optical element 203.

Accordingly, the first optical filter OF1 may be disposed in the first-first light-emitting area LE11. The first optical filter OF1 may be disposed in the second-first light-emitting area LE21. The first optical filter OF1 may be disposed in the second-second light-emitting area LE22. The second optical filter OF2 may be disposed in the second-third light-emitting area LE23. The first optical filter OF1 may be disposed in the first light-transmitting area LT1. The first optical filter OF1 may be disposed in the second light-transmitting area LT2. The second optical filter OF2 may be disposed in the third light-transmitting area LT3.

Accordingly, referring to FIG. 12, the first optical filter OF1 may be disposed in the first area NML. The first optical element 201 may be disposed in the first area NML. The first optical filter OF1 and the second optical filter OF2 may be disposed in the second area UD. The first optical element 201, the second optical element 202, and the third optical element 203 may be disposed in the second area UD.

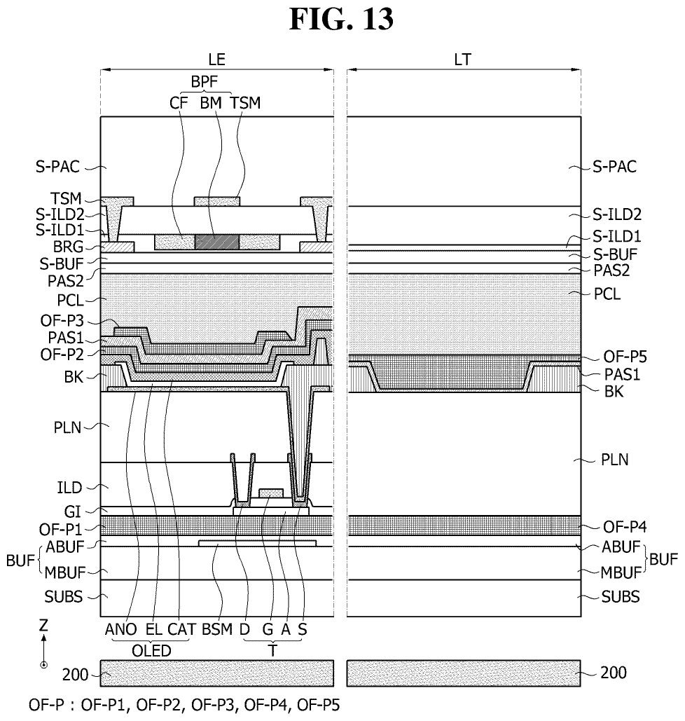

FIG. 13 is a cross-sectional view illustrating the display device according to one embodiment of the present specification.

Referring to FIG. 13, the display device may include the light-emitting area LE and the light-transmitting area LT. The above-described first area may include the light-emitting area LE. The above-described second area may include the light-emitting area LE and/or the light-transmitting area LT.

The light-emitting area LE may include a substrate SUBS, a buffer layer BUF, a gate insulation film GI, a transistor T, a bottom shield metal BSM, an interlayer dielectric film ILD, a planarization layer PLN, a light-emitting element layer in which a light-emitting element OLED is disposed, a bank BK, a first encapsulation layer PAS1, a second encapsulation layer PCL, a third encapsulation layer PAS2, a touch sensor electrode TSM, a bridge electrode BRG, a sensor buffer layer S-BUF, a first sensor interlayer dielectric film S-ILD1, a second sensor interlayer dielectric film S-ILD2, a sensor protection layer S-PAC, and a band-pass filter BPF including a color filter CF and a black matrix BM. In addition, the light-emitting area LE may include various electrodes or signal lines.

The light-transmitting area LT may include a substrate SUBS, a buffer layer BUF, a planarization layer PLN, a bank BK, a first encapsulation layer PAS1, a second encapsulation layer PCL, a third encapsulation layer PAS2, a sensor buffer layer S-BUF, a first sensor interlayer dielectric film S-ILD1, a second sensor interlayer dielectric film S-ILD2, and a sensor protection layer S-PAC.

The substrate SUBS may include a plurality of sub-substrates and intermediate films disposed between the sub-substrates. The intermediate film may be, for example, an inorganic film, and accordingly, moisture penetration can be blocked.

The bottom shield metal BSM may be disposed on the substrate SUBS. The bottom shield metal BSM may be disposed below an active layer of the transistor T. The bottom shield metal BSM may protect the active layer that is sensitive to light.

The buffer layer BUF may be a single film or a multi-film. When the buffer layer BUF is a multi-film, the buffer layer BUF may include a multi buffer layer MBUF and an active buffer layer ABUF.

A plurality of transistors T, a storage capacitor, and various electrodes or signal lines may be formed on the buffer layer BUF.

The transistors formed on the buffer layer BUF may be made of the same material and may be located in the same layer, but the present specification is not limited thereto.

The transistor T may include an active layer A, a first electrode S, a second electrode D, and a gate electrode G. The active layer A may be disposed on the buffer layer BUF. The gate insulation film GI may be disposed on the active layer A. The gate electrode G may be disposed on the gate insulation film GI, and the interlayer dielectric film ILD may be disposed on the gate electrode G.

The active layer A may include a channel area overlapping the gate electrode G, a source connection area located on one side of the channel area, and a drain connection area located on the other side of the channel area. The active layer A may include an oxide semiconductor material. For example, the oxide semiconductor material may include indium gallium zinc oxide (IGZO), indium gallium zinc tin oxide (IGZTO), ZnO, CdO, InO, zinc tin oxide (ZTO), and zinc indium tin oxide (ZITO). The active layer A may include a silicon-based semiconductor material. For example, the silicon-based semiconductor material may include low-temperature polycrystalline silicon (LTPS).

The first electrode S and the second electrode G of the transistor T may be disposed on the gate insulation film GI and the interlayer dielectric film ILD. The first electrode S and the second electrode G of the transistor T may be connected to a first source connection area and a first drain connection area in the active layer A through through-holes in the gate insulation film GI and the interlayer dielectric film ILD, respectively.

The planarization layer PLN may be disposed on the transistor T. The planarization layer PLN may be disposed on the first electrode S and the second electrode G of the transistor T.

Though not illustrated, a connection electrode that connects the first electrode S and the anode electrode ANO may be additionally disposed. The connection electrode may be an electrode that relays electrical connection between the first electrode S and the anode electrode ANO. The connection electrode may be connected to the first electrode S through a through-hole in the planarization layer PLN.

The light-emitting element OLED may be formed in the light-emitting element layer. The light-emitting element OLED may be driven by the transistor T. In an embodiment, the light-emitting element OLED may be an organic light-emitting element. In this case, the light-emitting element OLED may include the anode electrode ANO, the cathode electrode CAT, and a light emitting layer EL disposed between the anode electrode ANO and the cathode electrode CAT. The light-emitting layer EL may include an organic compound layer. The organic compound layer may include a hole injection layer (HIL), a hole transport layer (HTL), an emission layer (EML), an electron transport layer (ETL), and an electron injection layer (EIL), but the present specification is not limited thereto.

If a voltage is applied to the anode electrode ANO and the cathode electrode CAT of the light-emitting element OLED, holes passing through the hole transport layer and electrons passing through the electron transport layer may be moved to the emission layer to form excitons, and light having a wavelength range of visible light may be emitted from the emission layer. The light-emitting element OLED may have a tandem structure in which a plurality of emission layers are stacked. With the light-emitting element OLED having the tandem structure, the luminance and lifetime of the pixels can be improved. The light-emitting element layer may emit light of any one of red, green, blue, and white, but the present specification is not limited thereto. When the light-emitting element layer emits white light, light of any one of red, green, and blue may be emitted through the color filter CF disposed there above.

The anode electrode ANO may be connected to the first electrode S through a through-hole in the planarization layer PLN. The bank BK may be disposed on the anode electrode ANO.

The bank BK may overlap at least a part of the anode electrode ANO. The light-emitting layer EL may be disposed on the anode electrode ANO. The cathode electrode CAT may be disposed on the light-emitting layer EL.

The encapsulation layer may be disposed on the cathode electrode CAT. The encapsulation layer may be a layer that prevents or at least reduces moisture or oxygen from penetrating the light-emitting element OLED disposed below the encapsulation layer. The encapsulation layer can prevent moisture or oxygen from penetrating the light-emitting layer EL.

The encapsulation layer may be formed as a single layer or a multi-layer. The encapsulation layer may include a first encapsulation layer PAS1, a second encapsulation layer PCL, and a third encapsulation layer PAS2. The first encapsulation layer PAS1 and the third encapsulation layer PAS2 may be inorganic films, and the second encapsulation layer PCL may be an organic film. When the second encapsulation layer PCL is made of an organic film, the second encapsulation layer PCL may also serve as a planarization layer.

A touch sensor may be disposed on the encapsulation layer. The touch sensor may include the touch sensor electrode TSM and the bridge electrode BRG. The touch sensor may further include insulation films such as the sensor buffer layer S-BUF, the first sensor interlayer dielectric film S-ILD1, the second sensor interlayer dielectric film S-ILD2, and the sensor protection layer S-PAC.

The sensor buffer layer S-BUF may be disposed on the encapsulation layer. The bridge electrode BRG may be disposed on the sensor buffer layer S-BUF, and the first sensor interlayer dielectric film S-ILD1 and the second sensor interlayer dielectric film S-ILD2 may be disposed on the bridge electrode BRG.

The touch sensor electrode TSM may be disposed on the first sensor interlayer dielectric film S-ILD1 and the second sensor interlayer dielectric film S-ILD2. A part of the touch sensor electrode TSM may be connected to the bridge electrode BRG through holes in the first sensor interlayer dielectric film S-ILD1 and the second sensor interlayer dielectric film S-ILD2.

A plurality of touch sensor electrodes TSM may configure one touch electrode (or one touch electrode line) and may be disposed in a mesh and electrically connected. A part of the touch sensor electrode TSM and another part of the touch sensor electrode TSM may be electrically connected through the bridge electrode BRG, to configure one touch electrode (or one touch electrode line).

The sensor protection layer S-PAC may be disposed to cover the touch sensor electrode TSM and the bridge electrode BRG.

A color filter layer including the band-pass filter BPF may be disposed on the encapsulation layer. The band-pass filter BPF can prevent visible light from entering the touch sensor electrode TSM. Accordingly, the sensing sensitivity of the touch sensor can be improved. The band-pass filter BPF may be disposed to overlap the touch sensor electrode TSM in a thickness direction (for example, the Z-axis direction) of the display panel.

The band-pass filter BPF may include the color filter CF and the black matrix BM.

The color filter CF may be formed to substantially face the light-emitting layer EL. As described above, the color filter CF may selectively convert a wavelength range of light to be transmitted to implement any color selected from a group including red, green, and blue into a wavelength range corresponding to visible light.

The black matrix BM can prevent light from entering the touch sensor electrode TSM. Accordingly, the black matrix BM may be disposed below the touch sensor electrode TSM to overlap the touch sensor electrode TSM in the thickness direction of the display panel.

The black matrix BM may be disposed between the color filters CF that implement different colors or may be disposed between the color filters CF that implement the same color.

The display device according to the present specification can achieve a reduction in size of the optical element 200 by disposing the optical filter OF, which has been disposed in the existing third optical element, in the display panel including the light-emitting area LE and the light-transmitting area LT. Accordingly, the thickness of the display device can be reduced. Therefore, it is advantageous that the process may be optimized to reduce the production energy and to reduce the weight of the display device. In addition, the improvement of sensing quality can be achieved by applying the optical filter OF as an optical filter for filtering, for example, transmitting and/or blocking the first light and/or the second light.

Accordingly, the display device may further include an optical filter layer OF-P that is disposed in the display panel and includes the optical filter OF as described above. As illustrated in the cross-sectional view, the optical filter layer OF-P may be divided into a first optical filter layer OF-P1, a second optical filter layer OF-P2, a third optical filter layer OF-P3, a fourth optical filter layer OF-P4, and a fifth optical filter layer OF-P5 according to a position where the optical filter layer is disposed. However, the position where the optical filter layer OF-P is disposed is not limited to the positions illustrated in the drawing, and the scope of the present specification is defined only by the matters according to the claims.

The first optical filter layer OF-P1, the second optical filter layer OF-P2, the third optical filter layer OF-P3, the fourth optical filter layer OF-P4, and the fifth optical filter layer OF-P5 may be disposed between the substrate SUBS and the encapsulation layer PAS1, PCL, or PAS2. The first optical filter layer OF-P1, the second optical filter layer OF-P2, the third optical filter layer OF-P3, the fourth optical filter layer OF-P4, and the fifth optical filter layer OF-P5 may at least partially overlap the optical element 200 in a thickness direction (for example, the Z-axis direction) of the display device. For example, at least part of light entering the optical element 200 or light emitted from the optical element 200 may be transmitted through or blocked by the first optical filter layer OF-P1, the second optical filter layer OF-P2, the third optical filter layer OF-P3, the fourth optical filter layer OF-P4, and the fifth optical filter layer OF-P5. For example, the whole of the light may be transmitted through or blocked by the first optical filter layer OF-P1, the second optical filter layer OF-P2, the third optical filter layer OF-P3, the fourth optical filter layer OF-P4, and the fifth optical filter layer OF-P5.

The first optical filter layer OF-P1, the second optical filter layer OF-P2, and the third optical filter layer OF-P3 may be the optical filter layer OF-P that is disposed in the light-emitting area LE. The fourth optical filter layer OF-P4 and the fifth optical filter layers OF-P5 may be the optical filter layer OF-P that is disposed in the light-transmitting area LT. Since not only the first area but also the second area may include the light-emitting area LE, the first optical filter layer OF-P1, the second optical filter layer OF-P2, and the third optical filter layer OF-P3 disposed in the light-emitting area LE may be included in the first area and/or the second area. Since the second area may include the light-transmitting area LT, the fourth optical filter layer OF-P4 and the fifth optical filter layer OF-P5 disposed in the light-transmitting area LT may be included in the second area.

While an example where the optical filter layers are disposed in the drawing has been described due to a limit to the paper, all of the first optical filter layer OF-P1, the second optical filter layer OF-P2, the third optical filter layer OF-P3, the fourth optical filter layer OF-P4, and the fifth optical filter layer OF-P5 may not be in one display device.

For example, the display device may include only the first optical filter layer OF-P1. For example, the display device may include only the second optical filter layer OF-P2. For example, the display device may include only the third optical filter layer OF-P3. For example, the display device may include only the fourth optical filter layer OF-P4. For example, the display device may include only the fifth optical filter layer OF-P5.

For example, the display device may include the first optical filter layer OF-P1 and the second optical filter layer OF-P2. For example, the display device may include the first optical filter layer OF-P1 and the third optical filter layer OF-P3. For example, the display device may include the first optical filter layer OF-P1 and the fourth optical filter layer OF-P4. For example, the display device may include the first optical filter layer OF-P1 and the fifth optical filter layer OF-P5. For example, the display device may include the second optical filter layer OF-P2 and the third optical filter layer OF-P3. For example, the display device may include the second optical filter layer OF-P2 and the fourth optical filter layer OF-P4. For example, the display device may include the second optical filter layer OF-P2 and the fifth optical filter layer OF-P5. For example, the display device may include the third optical filter layer OF-P3 and the fourth optical filter layer OF-P4. For example, the display device may include the third optical filter layer OF-P3 and the fifth optical filter layer OF-P5. For example, the display device may include the fourth optical filter layer OF-P4 and the fifth optical filter layer OF-P5.

As described above, the optical filter layer OF-P illustrated in the drawing is to illustrate the position of the optical filter layer OF-P and is not intended to limit the number of optical filter layers OF-P that may be included in the display device. Numerous combinations of the first optical filter layer OF-P1, the second optical filter layer OF-P2, the third optical filter layer OF-P3, the fourth optical filter layer OF-P4, and the fifth optical filter layer OF-P5 may also be included in the display device according to the present specification.

The first optical filter layer OF-P1 may be disposed on the substrate SUBS. The first optical filter layer OF-P1 may be disposed between the substrate SUBS and the transistor T. The transistor T may be included in the above-described circuit layer. The first optical filter layer OF-P1 may be disposed between the buffer layer BUF and the gate insulation film GI. The first optical filter layer OF-P1 may be disposed between the bottom shield metal BSM and the active layer A.

The second optical filter layer OF-P2 may be disposed on the substrate SUBS. The second optical filter layer OF-P2 may be disposed between the substrate SUBS and the encapsulation layer PAS1, PCL, or PAS2. The second optical filter layer OF-P2 may be disposed on the planarization layer PLN. The second optical filter layer OF-P2 may be disposed on the light-emitting element OLED. The second optical filter layer OF-P2 may be disposed between the light-emitting element OLED and the encapsulation layer PAS1, PCL, or PAS2. The second optical filter layer OF-P2 may be disposed between the cathode electrode CAT and the first encapsulation layer PAS1.

The third optical filter layer OF-P3 may be disposed on the substrate SUBS. The third optical filter layer OF-P3 may be disposed between the substrate SUBS and the encapsulation layer PAS1, PCL, or PAS2. The third optical filter layer OF-P3 may be disposed on the planarization layer PLN. The third optical filter layer OF-P3 may be disposed on the light-emitting element OLED. The third optical filter layer OF-P3 may be disposed between the light-emitting element OLED and the encapsulation layer PAS1, PCL, or PAS2. The third optical filter layer OF-P3 may be disposed between the cathode electrode CAT and the second encapsulation layer PCL. The third optical filter layer OF-P3 may be disposed between the cathode electrode CAT and the third encapsulation layer PAS2. The third optical filter layer OF-P3 may be disposed between the first encapsulation layer PAS1 and the second encapsulation layer PCL.

The fourth optical filter layer OF-P4 may be disposed on the substrate SUBS. The fourth optical filter layer OF-P4 may be disposed between the substrate SUBS and the planarization layer PLN. The fourth optical filter layer OF-P4 may be disposed between the substrate SUBS and the transistor T. The fourth optical filter layer OF-P4 may not overlap the transistor T in the thickness direction of the display device. The fourth optical filter layer OF-P4 may be disposed between the buffer layer BUF and the encapsulation layer PAS1, PCL, or PAS2. The fourth optical filter layer OF-P4 may be disposed between the active buffer layer ABUF and the planarization layer PLN. The fourth optical filter layer OF-P4 may be formed in the same layer and of the same material as the first optical filter layer OF-P1.

The fifth optical filter layer OF-P5 may be disposed on the substrate SUBS. The fifth optical filter layer OF-P5 may be disposed between the substrate SUBS and the encapsulation layer PAS1, PCL, or PAS2. The fifth optical filter layer OF-P5 may be disposed between the planarization layer PLN and the encapsulation layer PAS1, PCL, or PAS2. The fifth optical filter layer OF-P5 may be disposed on the first encapsulation layer PAS1. The fifth optical filter layer OF-P5 may be disposed between the first encapsulation layer PAS1 and the second encapsulation layer PCL. The fifth optical filter layer OF-P5 may be formed in the same layer and of the same material as the third optical filter layer OF-P3.

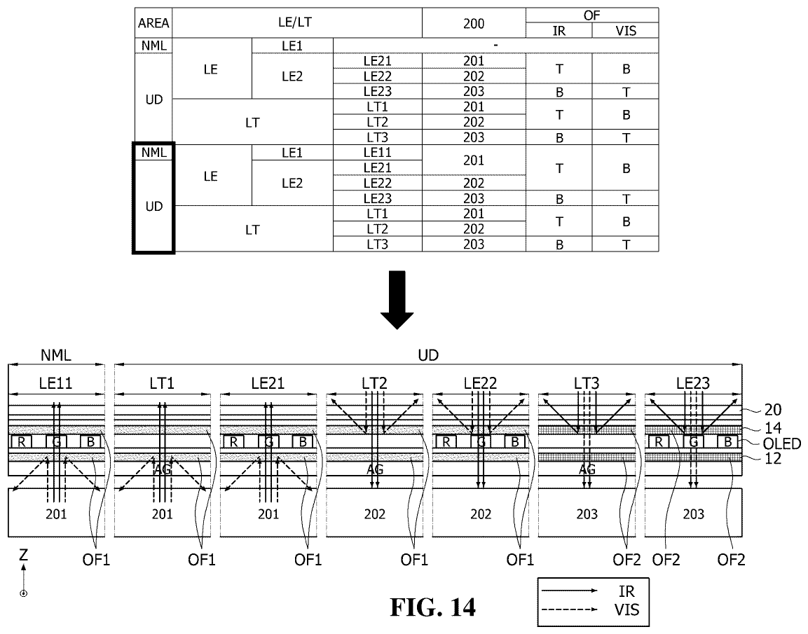

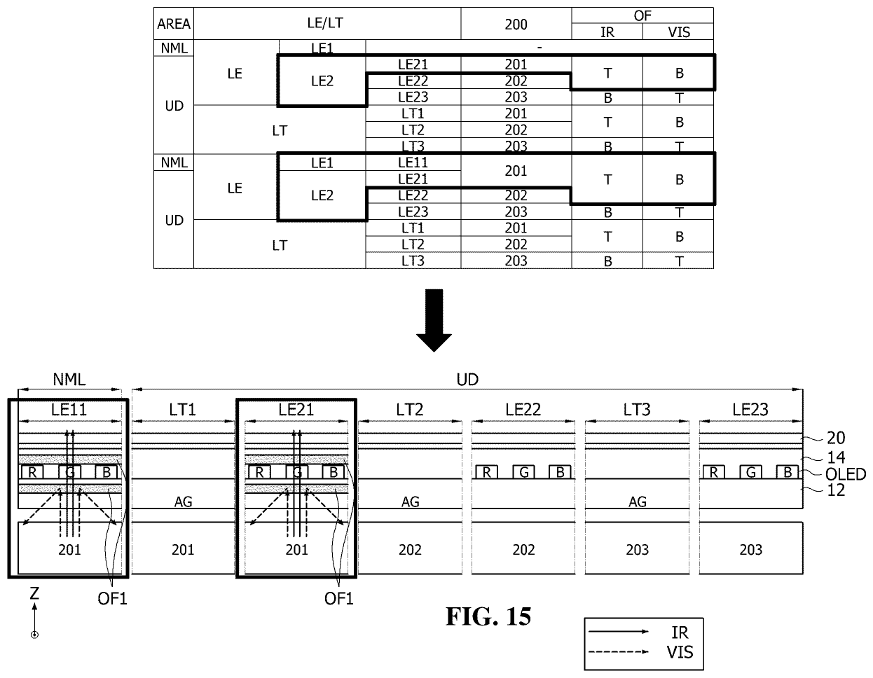

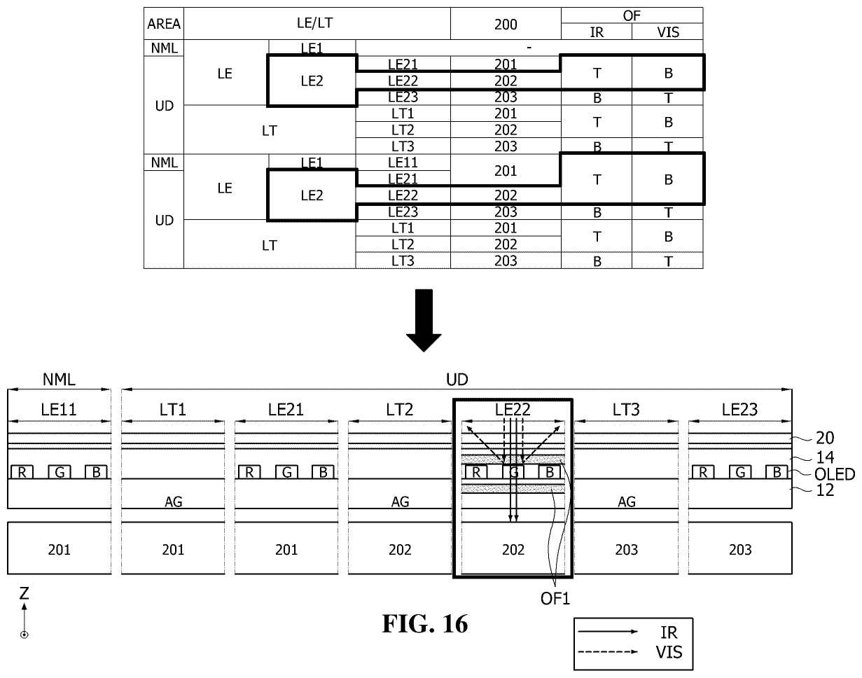

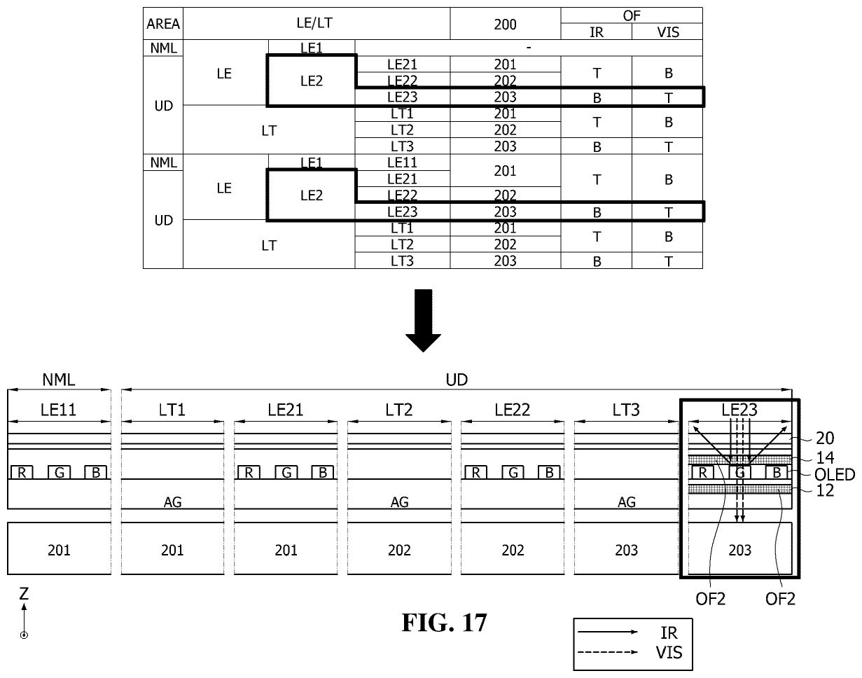

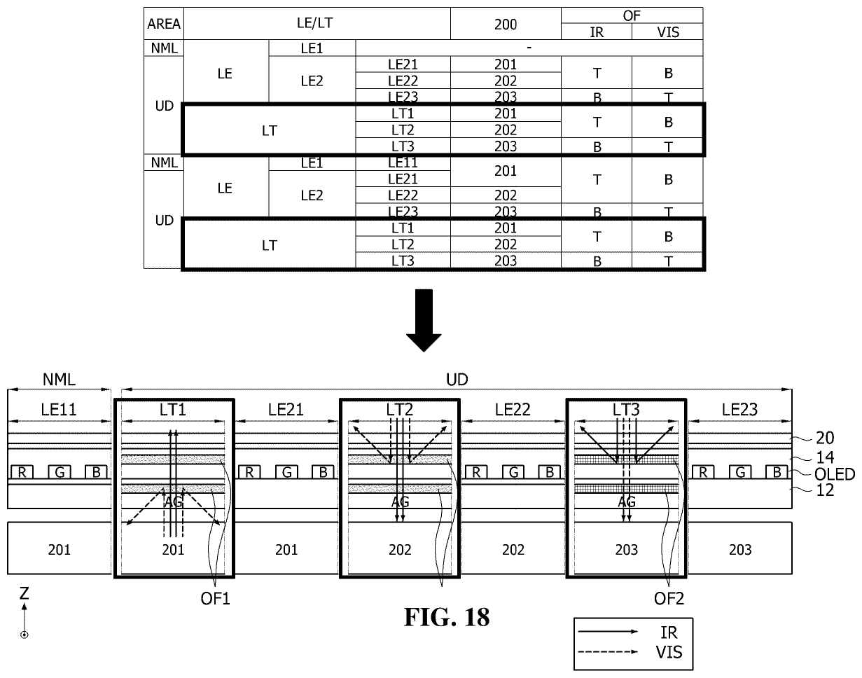

FIG. 14 is a chart and cross-sectional view illustrating optical elements and optical filters disposed by area of a display device according to an embodiment of the present specification. FIG. 15 is a chart and cross-sectional view illustrating a first optical element and an optical filter in a light-emitting area of a display device where the first optical element is disposed according to an embodiment of the present specification. FIG. 16 is a chart and cross-sectional view illustrating a second optical element and an optical filter in a light-emitting area of a display device where the second optical element is disposed according to an embodiment of the present specification. FIG. 17 is a chart and cross-sectional view illustrating a third optical element and an optical filter in a light-emitting area of a display device where the third optical element is disposed according to an embodiment of the present specification. FIG. 18 is a chart and cross-sectional view illustrating a first to third optical elements and optical filters in a light-transmitting area of a display device where the first to third optical elements are disposed according to an embodiment of the present specification. In the charts of FIGS. 14 to 18, ‘T’ may indicate transmitting and ‘B’ may indicate blocking.

Referring to FIG. 14, a traveling direction of the first light IR or the second light VIS may be determined by the type of the optical element 201, 202, or 203. For example, since the first optical element 201 emits the first light IR, the traveling direction of light may be a direction toward the outside of the display device. For example, since the second optical element 202 and the third optical element 203 sense the first light IR and the second light VIS, respectively, the traveling direction of the first light IR and the second light VIS may be a direction toward the inside of the display device.

As described above with reference to the cross-sectional view, optical filters OF1 and OF2 may be disposed inside the display panel. In the drawing, the optical filters OF1 and OF2 disposed above and below a light-emitting element OLED of a light-emitting element layer 14 are simplified and illustrated.

Referring to FIG. 15, the first optical filter OF1 may be disposed in the first-first light-emitting area LE11 and the second-first light-emitting area LE21 where the first optical element 201 is disposed. Accordingly, the first light IR out of light traveling in a direction from the inside toward the outside of the display device may be transmitted. The second light VIS may be blocked. The first light IR may be more selectively transmitted outside the display device than the second light VIS. When the first light IR is desired to reach an object disposed outside the display device, the display device according to the embodiment has an advantage of increasing the probability that the first light IR reaches the object outside the display device.

Referring to FIG. 16, the first optical filter OF1 may be disposed in the second-second light-emitting area LE22 where the second optical element 202 is disposed. Accordingly, the first light IR out of light traveling in a direction from the outside toward the inside of the display device may be transmitted. The second light VIS may be blocked. The first light IR may be more selectively transmitted inside the display device than the second light VIS. When the first light IR is desired to reach an element disposed inside the display device, the display device according to the embodiment has an advantage of increasing the probability that the first light IR reaches the element disposed inside the display device.

Referring to FIG. 17, the second optical filter OF2 may be disposed in the second-third light-emitting area LE23 where the third optical element 203 is disposed. Accordingly, the second light VIS out of light traveling in a direction from the outside toward the inside of the display device may be transmitted. The first light IR may be blocked. The second light VIS may be more selectively transmitted inside the display device than the first light IR. When the second light VIS is desired to reach the element disposed inside the display device, the display device according to the embodiment has an advantage of increasing the probability that the second light VIS reaches the element disposed inside the display device.

Referring to FIG. 18, the first optical filter OF1 may be disposed in the first light-transmitting area LT1 where the first optical element 201 is disposed. Accordingly, the first light IR out of light traveling in a direction from the inside toward the outside of the display device may be transmitted. The second light VIS may be blocked. The first light IR may be more selectively transmitted outside the display device than the second light VIS. When the first light IR is desired to reach an object disposed outside the display device, the display device according to the embodiment has an advantage of increasing the probability that the first light IR reaches the object disposed outside the display device.

The first optical filter OF1 may be disposed in the second light-transmitting area LT2 where the second optical element 202 is disposed. Accordingly, the first light IR out of light traveling in a direction from the outside toward the inside of the display device may be transmitted. The second light VIS may be blocked. The first light IR may be more selectively transmitted inside the display device than the second light VIS. When the first light IR is desired to reach an element disposed inside the display device, the display device according to the embodiment has an advantage of increasing the probability that the first light IR reaches the element disposed inside the display device.

The second optical filter OF2 may be disposed in the third light-transmitting area LT3 where the third optical element 203 is disposed. Accordingly, the second light VIS out of light traveling in a direction from the outside toward the inside of the display device may be transmitted. The first light IR may be blocked. The second light VIS may be more selectively transmitted inside the display device than the first light IR. When the second light VIS is desired to reach the element disposed inside the display device, the display device according to the embodiment has an advantage of increasing the probability that the second light VIS reaches the element disposed inside the display device.

Although embodiments of the present invention have been described in more detail with reference to the accompanying drawings, the present invention is not necessarily limited to these embodiments, and may be variously modified without departing from the technical idea of the present invention.

Accordingly, the embodiments disclosed herein are not intended to limit the technical spirit of the present invention but merely illustrate it, and the scope of the technical idea of the present invention is not limited by these embodiments.

Therefore, it should be understood that the embodiments described above are illustrative in all respects and are not limited.

The scope of protection of the present invention should be interpreted based on the claims, and all technical ideas within an equivalent scope thereof should be interpreted as being included in the scope of the present invention.

What is claimed is:

1. A display device comprising:
a display panel; and
an optical element below the display panel, the optical element configured to emit light to an outside of the display device and/or detect light from the outside of the display device,
wherein the display panel includes a substrate, an encapsulation layer on the substrate, and an optical filter layer between the substrate and the encapsulation layer,
wherein the optical filter layer filters the emitted light and/or the detected light.

2. The display device according to claim 1, further comprising:
a light-emitting element between the substrate and the encapsulation layer; and
a circuit layer between the substrate and the light-emitting element, the circuit layer configured to drive the light-emitting element,
wherein the optical filter layer is between the substrate and the circuit layer.

3. The display device according to claim 1, further comprising:
a light-emitting element between the substrate and the encapsulation layer,
wherein the light-emitting element includes a light-emitting layer, an anode electrode between the substrate and the light-emitting layer, and a cathode electrode between the encapsulation layer and the light-emitting layer, and
wherein the optical filter layer is on the light-emitting element.

4. The display device according to claim 1, further comprising:
a planarization layer between the substrate and the encapsulation layer,
wherein the optical filter layer is on the planarization layer.

5. The display device according to claim 1, further comprising:
a color filter layer on the encapsulation layer.

6. The display device according to claim 1, further comprising:
a touch sensor on the encapsulation layer, the touch sensor including a touch sensor electrode; and
a band-pass filter overlapping the touch sensor electrode in a thickness direction of the display panel.

7. The display device according to claim 1, wherein the display panel includes:
a first area including a first light-emitting area, and
a second area including a light-transmitting area and a second light-emitting area,
wherein the optical element includes at least one of a first optical element including a light source configured to emit a first light, a second optical element including a sensor configured to sense the first light, and a third optical element including a sensor configured to sense a second light that has a different wavelength range from that of the first light, and
wherein the optical filter layer includes at least one of a first optical filter configured to transmit the first light and a second optical filter configured to transmit the second light.

8. The display device according to claim 7, wherein the optical element includes the first optical element that overlaps the first light-emitting area in a thickness direction of the display panel, and
wherein the first light-emitting area includes a first-first light-emitting area that overlaps the first optical element in the thickness direction of the display panel.

9. The display device according to claim 8, wherein the optical filter layer includes the first optical filter that overlaps the first-first light-emitting area in the thickness direction of the display panel.

10. The display device according to claim 7, wherein the optical element includes the first optical element that overlaps the second light-emitting area in a thickness direction of the display panel, and
wherein the second light-emitting area includes a second-first light-emitting area that overlaps the first optical element in the thickness direction of the display panel.

11. The display device according to claim 10, wherein the optical filter layer includes the first optical filter that overlaps the second-first light-emitting area in the thickness direction of the display panel.

12. The display device according to claim 7, wherein the optical element includes the second optical element that overlaps the second light-emitting area in a thickness direction of the display panel, and
wherein the second light-emitting area includes a second-second light-emitting area that overlaps the second optical element in the thickness direction of the display panel.

13. The display device according to claim 12, wherein the optical filter layer includes the first optical filter that overlaps the second-second light-emitting area in the thickness direction of the display panel.

14. The display device according to claim 7, wherein the optical element includes the third optical element that overlaps the second light-emitting area in a thickness direction of the display panel, and
wherein the second light-emitting area includes a second-third light-emitting area that overlaps the third optical element in the thickness direction of the display panel.

15. The display device according to claim 14, wherein the optical filter layer includes the second optical filter that overlaps the second-third light-emitting area in the thickness direction of the display panel.

16. The display device according to claim 7, wherein the optical element includes the first optical element that overlaps the light-transmitting area in a thickness direction of the display panel, and
wherein the light-transmitting area includes a first light-transmitting area that overlaps the first optical element in the thickness direction of the display panel.

17. The display device according to claim 16, wherein the optical filter layer includes the first optical filter that overlaps the first light-transmitting area in the thickness direction of the display panel.

18. The display device according to claim 7, wherein the optical element includes the second optical element that overlaps the light-transmitting area in a thickness direction of the display panel, and
wherein the light-transmitting area includes a second light-transmitting area that overlaps the second optical element in the thickness direction of the display panel.

19. The display device according to claim 18, wherein the optical filter layer includes the first optical filter that overlaps the second light-transmitting area in the thickness direction of the display panel.

20. The display device according to claim 7, wherein the optical element includes the third optical element that overlaps the light-transmitting area in a thickness direction of the display panel,
wherein the light-transmitting area includes a third light-transmitting area that overlaps the third optical element in the thickness direction of the display panel.
